(19) United States
(12) Patent Application Publication
(10) Pub. No.: US 2014/0367630 A1
(43) Pub. Date: Dec. 18, 2014

(54) SEMICONDUCTOR DEVICE AND METHOD FOR MANUFACTURING SAME

(71) Applicant: PS4 LUXCO S.A.R.L., Luxembourg (LU)

(72) Inventor: ISAMU ASANO, Tokyo (JP)

(21) Appl. No.: 14/306,002

(22) Filed: Jun. 16, 2014

(30) Foreign Application Priority Data
Jun. 17, 2013 (JP) 2013-126470

(51) Int. Cl. H01L 45/00

(52) U.S. Cl. CPC H01L 45/126; H01L 45/1675
USPC 257/4; 438/382

(57) ABSTRACT

A semiconductor device includes: a lower electrode, a heater electrode having a pillar shape erected on the lower electrode, a phase change material in contact with the upper portion of the heater electrode, an upper electrode disposed above a heater electrode via the phase change material, side wall portions enclosing the periphery of the heater electrode, a first insulating film configuring a bottom surface portion continuous between heater electrodes, and a second insulating film formed on a bottom surface portion of the first insulating film; wherein the first insulating film and the second insulating film are formed after the heater electrode is formed in a pillar shape by double patterning.

### TECHNICAL FIELD

The present invention relates to a semiconductor device and a method for manufacturing the same, and more specifically relates to a phase change memory semiconductor device and a method for manufacturing the same.

### BACKGROUND ART

Phase change memory (hereinafter referred to as PRAM) that uses a resistance value change of a phase change material is being developed for nonvolatile memory widely used as information storage means for mobile devices and the like.

The PRAM is an element that uses a phase change layer (chalcogenide semiconductor thin film and the like), in which the electrical resistance changes according to a crystalline state, in a memory cell. Known chalcogenide semiconductors used in phase change memory include GeSbTe (hereinafter, referred to as GST), which is a compound of Ge (germanium), Te (tellurium), and Sb (antimony), or AsSbTe, SeSbTe, and the like.

Chalcogenide semiconductors can have two stable states: a noncrystalline state and a crystalline state, and transitioning to a crystalline state from a noncrystalline state requires supplying heat that exceeds an energy barrier. Storing digital information is made possible by corresponding a noncrystalline state, which exhibits high resistance, as the digital value “1” and corresponding a crystalline state, which exhibits low resistance, as the digital value “0”. Further, detecting the differences in current amounts (or voltage drops) flowing through the chalcogenide semiconductor enables a determination to be made whether the stored information is “1” or “0”.

Joule heat is used as the heat supplied for the phase change of the chalcogenide semiconductor. That is, supplying pulses of different peak values and time widths to the chalcogenide semiconductor generates joule heat in the vicinity of a contact surface of an electrode and the chalcogenide semiconductor, thereby generating a phase change due to the joule heat.

Specifically, supplying heat near the melting point to the chalcogenide semiconductor for a short time and then cooling rapidly transitions the chalcogenide semiconductor to a noncrystalline state. Conversely, supplying a crystallization temperature lower than the melting point for a long period of time to the chalcogenide semiconductor and then cooling it transitions the chalcogenide semiconductor to a crystalline state.

Transitioning to the crystalline state from the noncrystalline state is referred to as “setting (crystallization process),” and the pulse applied to the chalcogenide semiconductor at this time is referred to as a “set pulse.” Here, the minimum required temperature (crystallization temperature) for crystallization is designated as Tc, and the minimum required time (crystallization time) for crystallization is designated as tr.

Conversely, transitioning to the noncrystalline state from the crystalline state is referred to as “resetting (noncrystallization process),” and the pulse applied to the chalcogenide semiconductor at this time is referred as a “reset pulse.” At this time, the heat applied to the chalcogenide semiconductor is a heat near the melting point Tm, and the chalcogenide semiconductor is rapidly cooled after melting.

Reducing power consumption requires forming a heater electrode having an even smaller diameter.

Therefore, a technique is known where side walls are formed using an insulating film made of a silicon nitride film or the like on the side surface portions of the opening for the heater electrode, and the inner portion thereof is filled with a heater electrode material (Patent Documents 1 and 2).

### BACKGROUND DOCUMENTS

### Patent Documents

Patent Document 1: Japanese Unexamined Patent Application Publication No. 2008-71797A

Patent Document 2: Japanese Unexamined Patent Application Publication No. 2009-212202A

### SUMMARY OF INVENTION

### Technical Problem

A method for forming the conventional heater electrode will be described with reference to FIGS. 13A-13C. First, a second interlayer film 33 is formed on a first interlayer film 31 where a contact plug 32 is formed as a lower electrode, and patterning is performed on a hole 34A using photolithography (FIG. 13(a)). Next, side walls 35 are formed by insulating films to create a hole portion 34B having a reduced opening diameter (FIG. 13(b)). The heater electrode conductive material is filled in the hole portion 34B to form a heater electrode 36 (FIG. 13(c)). The heater diameter may be conceivably reduced by increasing the thickness of the films on the side walls 35, but, as illustrated by the dashed line portion in FIG. 13(b), because the side wall insulating film is deposited in substantially the same thickness as the side wall portion, this will need to be removed by etching back. Increasing the thickness of the films requires over-etching to be conducted to ensure opening properties at the bottom of the opening portion. Because increasing the amount of over-etching reduces the film thickness of the side walls that should be retained on the side walls of the hole 34A, this has an opposite effect on reducing the contact area of the heater electrode and the phase change layer. A proposal is given in Patent Document 2 to further sharpen a tip end portion of the heater electrode enclosed by side walls, but there is still room for further improvement as this increases the number of steps.

### Means for Solving the Problem

That is, according to one embodiment of the present invention, a semiconductor device is provided having: a lower electrode; a heater electrode having a pillar shape erected on the lower electrode; a phase change material in contact with an upper surface of the heater electrode; an upper electrode disposed above the heater electrode via the phase change material; a side wall portion enclosing the periphery of the heater electrode; a first insulating film configuring a bottom surface portion continuous between the heater electrodes; and a second insulating film formed on a bottom surface portion of the first insulating film.

Furthermore, in a different embodiment of the present invention, a method for manufacturing a semiconductor device is provided including:
a step for forming a laminated structure of a heater electrode material layer and a hard mask layer on a lower electrode;
a step for forming a first line pattern mask extending in a first direction passing though above the lower electrode on the hard mask layer;
a step for forming a hard mask fin by etching the hard mask layer using the first line pattern mask as a mask;
a step for forming a second line pattern mask extending in a second direction intersecting the first direction and passing above the lower electrode after removing the first line pattern mask;
a step for forming a hard mask pillar by etching the hard mask fin using the second line pattern mask as a mask; and
a step for forming a heater electrode by etching the heater electrode layer using the hard mask pillar as a mask.

Furthermore, according to another embodiment of the present invention, a method for manufacturing a semiconductor device that includes a phase change memory is provided including:
a heater electrode having a pillar shape erected on a lower electrode; an interlayer insulating film enclosing the heater electrode; a phase change material in contact with an upper surface of the heater electrode; and an upper electrode opposing the heater electrode via the phase change material, wherein the interlayer insulating film is formed after the heater electrode having a pillar shape is formed by a double patterning method.

### Advantageous Effects of Invention

According to the present invention, rather than forming by embedding the heater electrode into the hole portion formed by the side walls as in the conventional technique, a flat film can be formed into a fine pillar shape at or below the limits of photolithography using double patterning, thereby increasing current density, improving heating efficiency, and reducing the current required for rewriting (phase change).

### BRIEF DESCRIPTION OF THE DRAWINGS

FIG. 1 is a schematic view describing a semiconductor device according to one embodiment of the present invention, and (a) illustrates a plan view, and (b) illustrates a cross-sectional view of (a) along the line A-A′.

FIG. 2 is a step cross-sectional view describing the manufacturing method of the semiconductor device according to one embodiment of the present invention, and (a) illustrates a plan view, and (b) illustrates a cross-sectional view of (a) along the line A-A′.

FIG. 3 is a step cross-sectional view describing the manufacturing method of the semiconductor device according to one embodiment of the present invention, and (a) illustrates a plan view, and (b) illustrates a cross-sectional view of (a) along the line A-A′.

FIG. 4 is a step cross-sectional view describing the manufacturing method of the semiconductor device according to one embodiment of the present invention, and (a) illustrates a plan view, (b) illustrates a cross-sectional view of (a) along the line A-A′, and (c) illustrates a cross-sectional view of (a) along the line B-B′.

FIG. 5 is a step cross-sectional view describing the manufacturing method of the semiconductor device according to one embodiment of the present invention, and (a) illustrates a plan view, (b) illustrates a cross-sectional view of (a) along the line A-A′, and (c) illustrates a cross-sectional view of (a) along the line B-B′.

FIG. 6 is a step cross-sectional view describing the manufacturing method of the semiconductor device according to one embodiment of the present invention, and (a) illustrates a plan view, (b) illustrates a cross-sectional view of (a) along the line A-A′, and (c) illustrates a cross-sectional view of (a) along the line B-B′.

FIG. 7 is a step cross-sectional view describing the manufacturing method of the semiconductor device according to one embodiment of the present invention, and (a) illustrates a plan view, (b) illustrates a cross-sectional view of (a) along the line A-A′, and (c) illustrates a cross-sectional view of (a) along the line B-B′.

FIG. 8 is a step cross-sectional view describing the manufacturing method of the semiconductor device according to one embodiment, and (a) illustrates a plan view, and (b) illustrates a cross-sectional view of (a) along the line A-A′.

FIG. 9 is a step cross-sectional view describing the manufacturing method of the semiconductor device according to one embodiment, and (a) illustrates a plan view, and (b) illustrates a cross-sectional view of (a) along the line A-A′.

FIG. 10 is a schematic cross-sectional view illustrating the structure of the semiconductor device according to a different embodiment of the present invention.

FIG. 11 is a schematic cross-sectional view illustrating the structure of the semiconductor device according to a different embodiment of the present invention.

FIG. 12 is a schematic cross-sectional view illustrating the structure of the semiconductor device according to a different embodiment of the present invention.

FIGS. 13A-13C are the step cross-sectional views describing a manufacturing process of a conventional heater electrode.

### DETAILED DESCRIPTION OF THE INVENTION

Embodiments of the present invention are described below with reference to the drawings

### First Embodiment

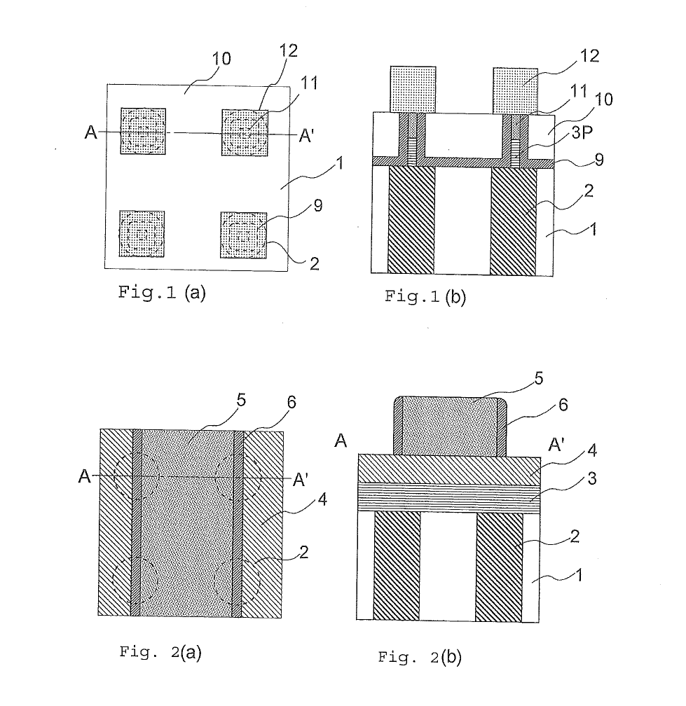

FIG. 1 is a schematic cross-sectional view describing the semiconductor device that becomes an embodiment of the present invention. A contact plug 2 electrically connected to a semiconductor element formed on a semiconductor substrate, not shown, is provided on a first interlayer insulating film 1, a heater electrode 3P having a pillar shape is laminated on an upper surface of the contact plug 2, and a phase change material layer 11 of a GST or the like is laminated on an upper portion of the heater electrode 3P. At the [ku-ku], the contact plug 2 functions as a lower electrode in a phase change memory element. A first insulating film 9 having a side wall shape surrounding a laminated structure of the heater electrode 3P and the phase change material layer 11 is provided, and the first insulating film 9 configures a bottom surface portion that is continuous between the heater electrodes on the first interlayer insulating film 1. A second insulating film 10 that fills the gap between the heater electrodes is formed on the first insulating film 9. The material of the second insulating film differs from that of the first insulating film, and, for example, a silicon nitride film and the like may be used as the first insulating film, and a silicon hydride film and the like may be used as the second insulating film. The first and second insulating films together are referred to as a second interlayer insulating film.

An upper electrode 12 opposing the heater electrode 3P is provided on the second interlayer insulating film, and the crystalline state of the phase change material layer 11 can be controlled by applying a predetermined voltage between the heater electrode 3P and the upper electrode 12. For example, after supplying heat to the GST for a short time (1 to 10 ns) near the melting point (about 610° C.), the GST becomes a noncrystalline state if it is cooled rapidly (about 1 ns). Conversely, GST becomes a crystalline state if cooled after heat of a crystallization temperature (about 450° C.) is applied to the GST for a long period of time (30 to 50 ns). With the present invention, a semiconductor device with low power consumption can be provided because the upper surface area of the heater electrode is small, and thus the power consumption for carrying out such a state change in the phase change material layer 11 is reduced.

Next, a method for manufacturing the semiconductor device according to the present embodiment will be described with reference to FIGS. 2 to 9.

As illustrated in FIG. 2, the contact plug 2 electrically connected to the semiconductor element formed on the semiconductor substrate, not shown, is formed on the first interlayer insulating film 1. The contact plug 2 configures the lower electrode of a phase change memory element and can use metal plugs such as, for example, tungsten (W) or the like. Although not shown for simplicity sake, the contact plug 2 may be configured with a barrier metal (Ti/TiN) and a W plug.

A laminated film of a heater electrode material layer 3 and a hard mask layer 4 is formed on the first interlayer insulating film 1. A material with a slightly higher resistance than the contact plug 2, for example, a titanium nitride film or the like, may be used as the heater electrode material layer. A material that is easy to remove in subsequent steps may be used for the hard mask layer 4, and in this case, a polysilicon or amorphous carbon film, or the like may be used. A first photoresist pattern 5 is formed on the hard mask layer 4 as a line pattern extending in the vertical direction of the paper surface (first direction) of FIG. 2(a), and a first side wall 6, made of silicon nitride film or the like, is formed on both side walls thereof. The film thickness of a first side wall 6 and the width of the first photoresist pattern 5 are adjusted such that the first side wall 6 passes through substantially the center of the contact plug 2. The first side wall 6 is referred to as a first line pattern mask. The film thickness of the first side wall 6 is a film thickness at or below the photolithography limit, for example, a thickness of not more than 20 nm and preferably not more than 10 nm. The lower limit of the thickness of the first side wall 6 may be adjusted within a range in which the patterning of the hard mask layer 4 can be normally performed using this as a mask and in which the strength of the formed hard mask fin can be maintained.

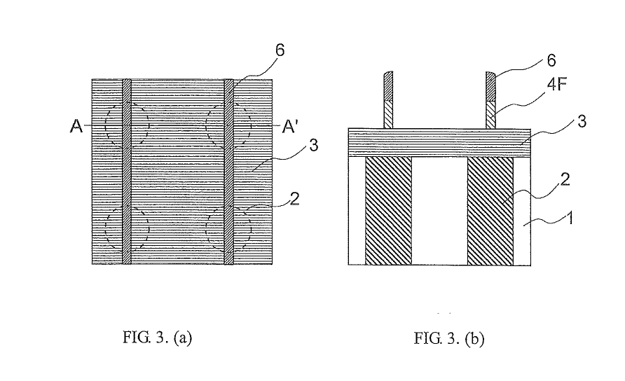

Next, as illustrated in FIG. 3, after the first photoresist pattern 5 is removed, the hard mask layer 4 is etched through dry etching with the first side wall 6 used as a mask, and a hard mask fin 4F is formed.

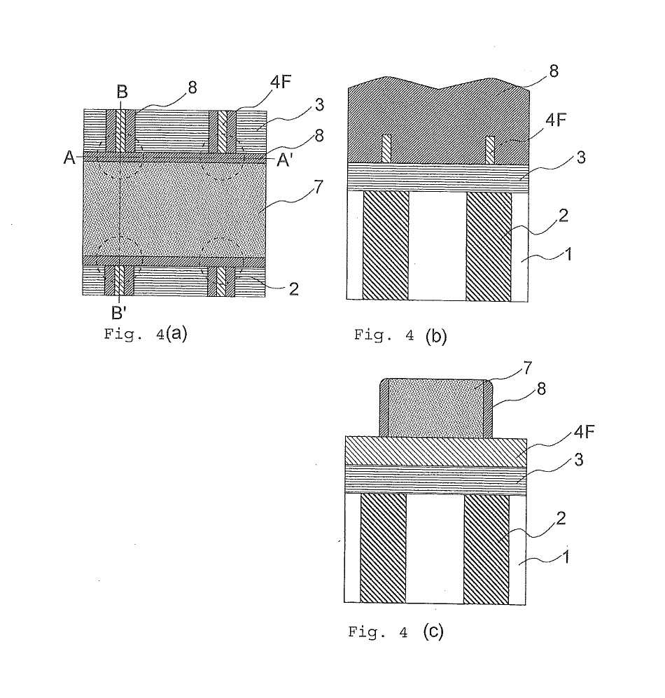

After the remaining first side wall 6 is removed, a second photoresist pattern 7 is formed extending in a second direction (orthogonally) intersecting the first direction in FIG. 2(a) to further form a second side wall 8 made of silicon nitride film or the like (FIG. 4). The side wall 8 is also formed on a side wall of the hard mask fin 4F. The film thickness of the second side wall 8 and the width of the second photoresist pattern 7 are adjusted so the second side wall 8 of the side wall portion of the second photoresist pattern 7 passes through substantially the center of the contact plug 2. The second side wall 8 of the side wall portion of the second photoresist pattern 7 is referred to as a second line pattern mask. The film thickness of the second side wall 8 is a film thickness at or below the photolithography limit, for example, a thickness of not more than 20 nm and preferably not more than 10 nm The lower limit of the film thickness of the second side wall 8 may be adjusted within a range in which the patterning of the hard mask fin 4F can be normally fanned using this as a mask and in which the strength of the formed hard mask pillar 4P can be maintained.

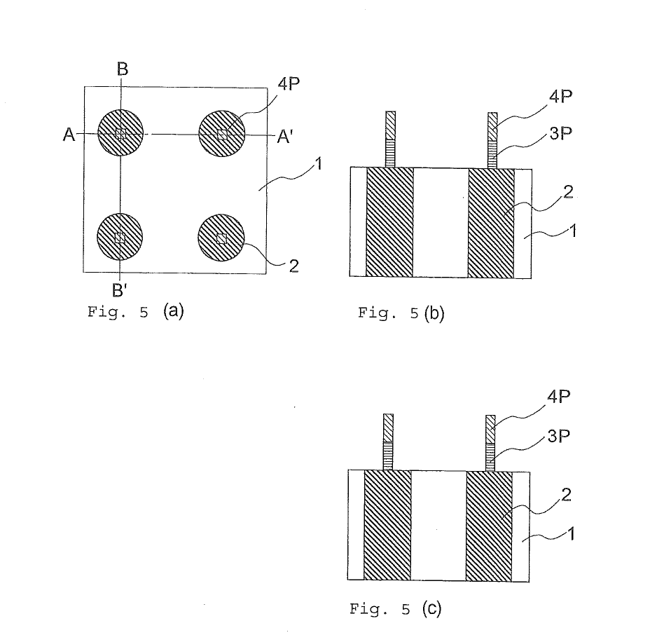

Next, as illustrated in FIG. 5, after the second photo resist pattern 7 is removed, the hard mask fin 4F is etched through dry etching using the second side wall 8 as a mask, and a hard mask pillar 4P is formed. Furthermore, after the second side wall 8 is removed, the heater electrode material layer 3 is etched by dry etching the hard mask pillar 4P to the mask to form the heater electrode 3P having a pillar shape.

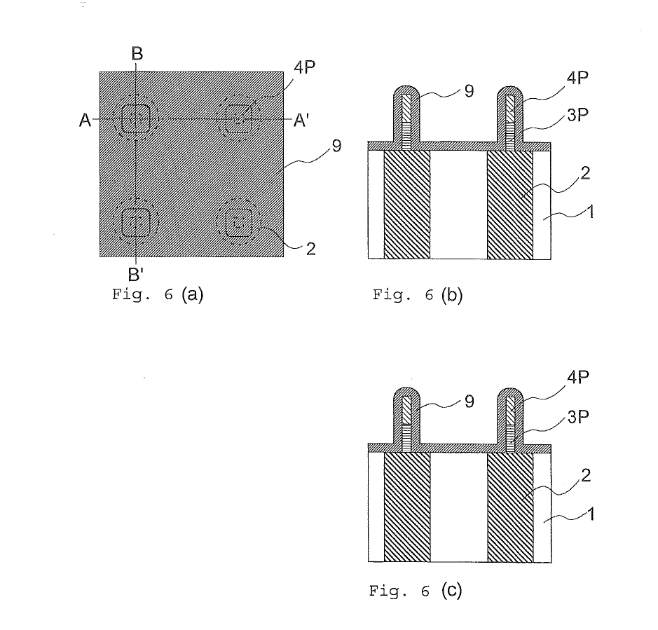

As illustrated in FIG. 6, a first insulating film 9 is fixated over the entire surface. The first insulating film 9 is an insulating film having oxidation resistance properties, and for which, a silicon nitride film,or the like, may be used. The first insulating film 9 is formed conformally at a thickness that is thinner than the height of the heater electrode 3P. The first insulating film 9 is formed to prevent the heater electrode and the phase change material layer described below from being oxidized due to contact with the silicon oxide film or the like during heating of the heater electrode. It is preferably formed to a film thickness of not less than 5 nm.

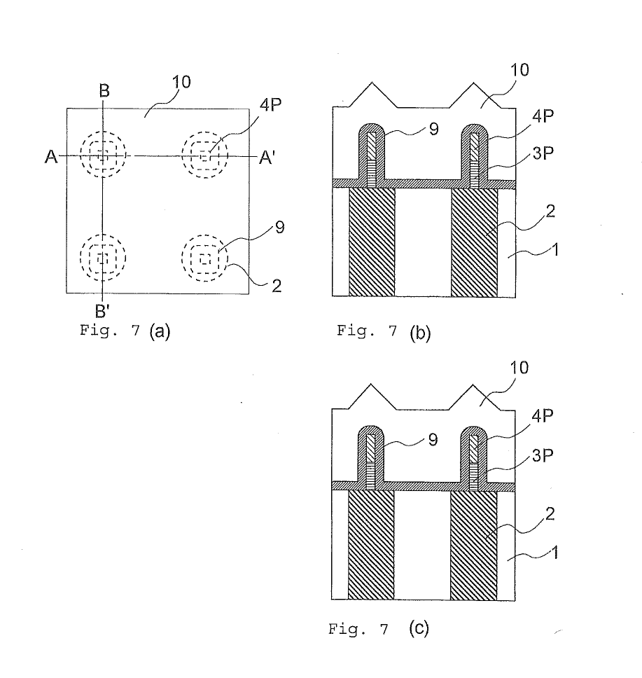

Next, as illustrated in FIG. 7, the silicon oxide film is foamed on the entire surface as the second insulating film 10 up to a height of, or higher than, the pillars (4P and 3P) covered by the first insulating film.

The second insulating film 10 and the first insulating film 9 are polished and flattened by a chemical mechanical polishing (CMP) method or the like to expose a hard mask pillar 4P. Next, the hard mask pillar 4P is selectively removed (FIG. 9), and subsequently, the hole formed by removing the hard mask pillar 4P is filled with the phase change material 11, and the upper electrode 12 is formed on the upper surface to complete a phase change memory element illustrated in FIG. 1.

In the present embodiment, the first side wall 6 and the second side wall 8 formed on the side walls of the photoresist are used as the first line pattern mask and the second line pattern mask, but the present invention is not limited thereto, and a well-known double patterning technique may be used such as slimming a line pattern formed by photolithography.

In this manner, according to the present invention, the contact area of the heater electrode 3P and the phase change material can be reduced through double patterning without sacrificing the contact resistance of the heater electrode 3P and the lower electrode (contact plug 2), and without requiring a complicated process, and it is possible to increase the current density, to improve the heating efficiency, and to reduce the current required for rewriting (phase change).

### Second Embodiment

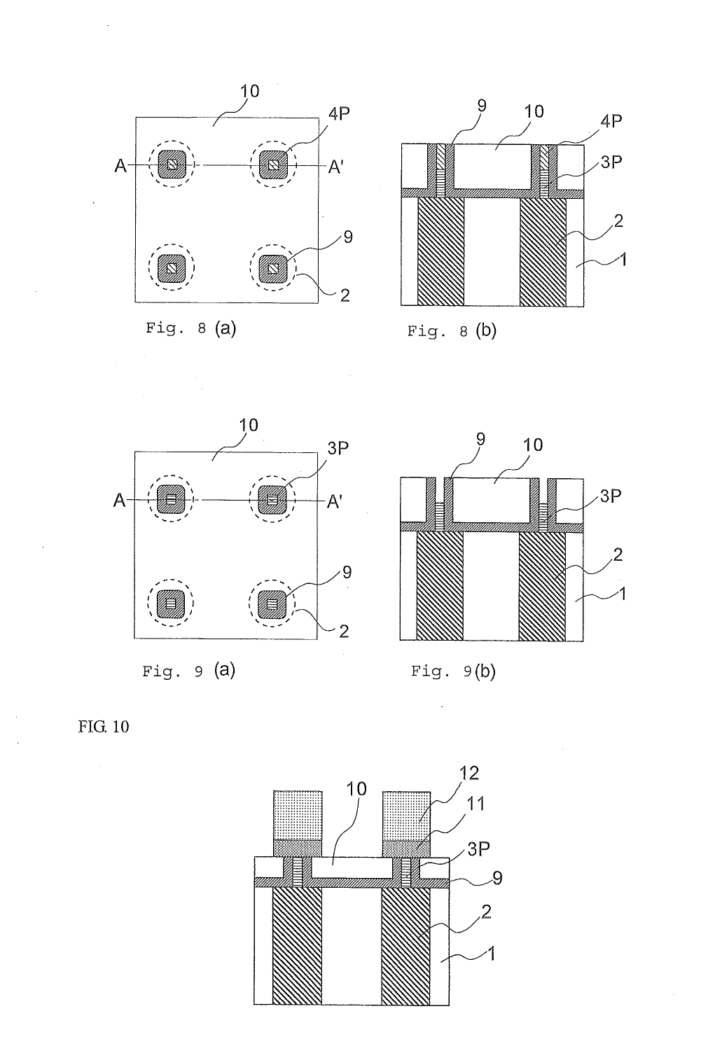

FIG. 10 illustrates a cross-sectional view of a phase change memory element according to the second embodiment of the present invention, and illustrates a structure in which only the heater electrode 3P is enclosed by the side wall portion of the first insulating film 9. In such a structure, a phase change material layer and an upper electrode layer are formed and can be prepared by forming the phase change material 11 and the upper electrode 12 by patterning, respectively, after performing the CMP step in FIG. 8 of the first embodiment until the upper surface of the heater electrode 3P is exposed. Furthermore, in the first embodiment, an example was given in which the hard mask layer 4 is formed of different material than the first insulating film 9 and the second insulating film 10, but in the present embodiment, the same material as the first insulating film 9 or the second insulating film 10 may be used in the hard mask layer 4.

### Third Embodiment

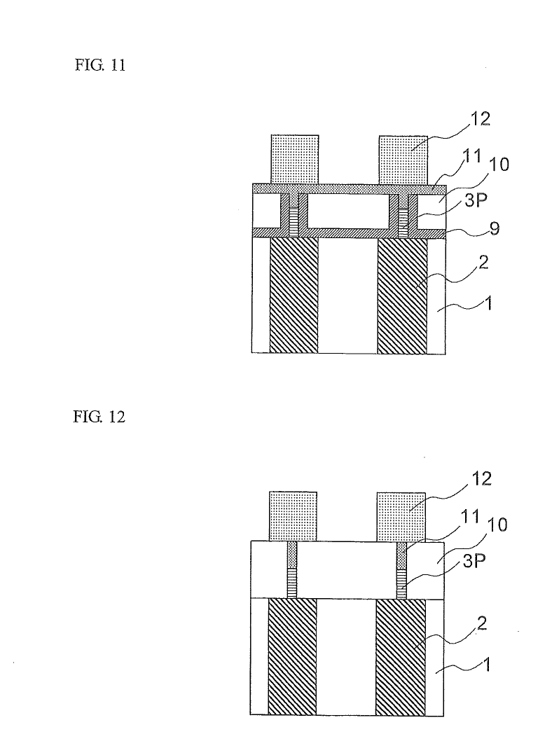

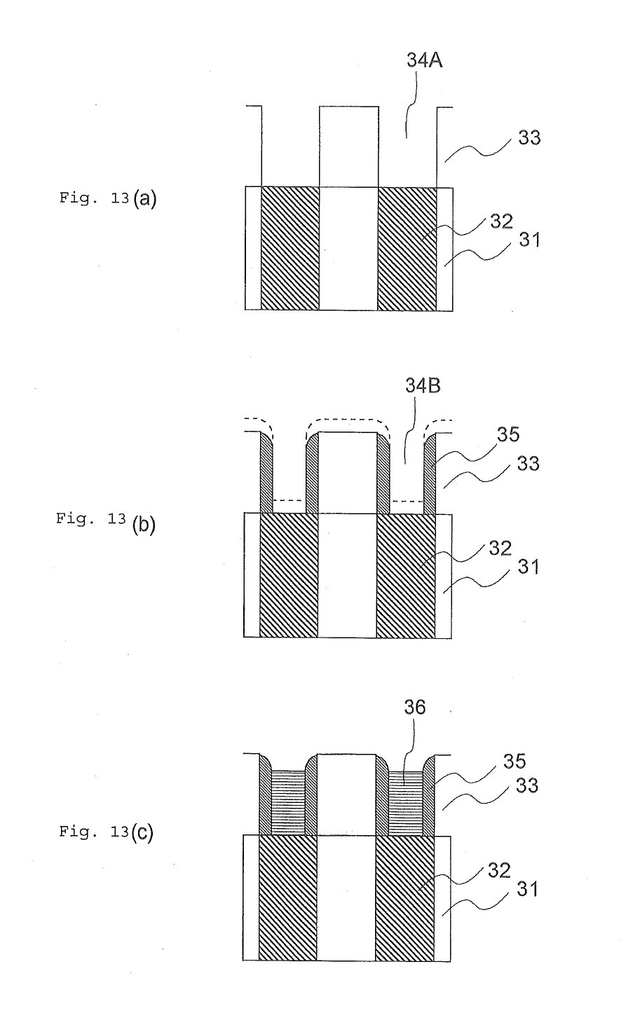

FIG. 11 illustrates still another embodiment of the present invention. In FIG. 1, the phase change material 11 was removed leaving only the portion enclosed by the side wall portion of the first insulating film 9, but the phase change material 11 may be left in succession, as illustrated in FIG. 11 since it is an amorphous material having a high resistance in the initial state. Furthermore, this may also be applied in the second embodiment.

### Fourth Embodiment

FIG. 12 is a cross-sectional view illustrating the fourth embodiment of the present invention and illustrates a state where the first insulating film 9 in the first embodiment is omitted. The first insulating film 9 for preventing oxidation is not required when the heater electrode material 3 and the phase change material 11 are materials that are less susceptible to oxidation or the second insulating film is a film other than a silicon oxide film

In the above embodiment, a description is given of using an independent electrode as the upper electrode and the contact plug 2 as a lower electrode, but the present invention is not limited thereto, and it is also possible to cross a lower wiring layer and an upper wiring layer in a matrix shape to form a matrix array shaped phase change memory element where the lower wiring layer and the upper wiring layer are used respectively as the lower electrode and the upper electrode.

### REFERENCE NUMERALS

1: First interlayer insulating film
2: Contact plug (lower electrode)
3: Heater electrode material layer
3P: Heater electrode
4: Hard mask layer
4F: Hard mask fin
4P: Hard mask pillar
5: First photoresist pattern
6: First side wall
7: Second photoresist pattern
8: Second side wall
9: First insulating film
10: Second insulating film
11: Phase change material
12: Upper electrode

What is claimed is:

1. A semiconductor device comprising:
a lower electrode;
a heater electrode having a pillar shape erected on the lower electrode;
a phase change material in contact with an upper surface of the heater electrode;
an upper electrode disposed above the heater electrode via the phase change material;
a side wall portion enclosing the periphery of the heater electrode;
a first insulating film configuring a bottom surface portion continuous between the heater electrodes; and
a second insulating film formed on a bottom surface portion of the first insulating film.

2. The semiconductor device according to claim 1, wherein the first insulating film is an insulating film having oxidation resistant properties, and the second insulating film is an insulating film that includes oxygen.

3. The semiconductor device according to claim 2, wherein the first insulating film is a silicon nitride film, and the second insulating film is a silicon oxide film.

4. The semiconductor device according to claim 1, wherein the phase change material is above the heater electrode and is formed at least within a range enclosed by the side wall portion.

5. The semiconductor device according to claim 4, wherein the upper surface of the phase change material is substantially the same as the upper surface of the side wall portion.

6. The semiconductor device according to claim 1, wherein the upper surface of the heater electrode is substantially the same as the upper surface of the side wall portion.

7. The semiconductor device according to claim 1, wherein the lower electrode is a contact plug formed in a lower interlayer insulating film.

8. The semiconductor device according to claim 7, wherein the side wall portion encloses the periphery of the heater electrode with a smaller range than the upper surface of the contact plug.

9. A method for manufacturing of a semiconductor device comprising:
a step for forming a laminated structure of a heater electrode material layer and a hard mask layer on a lower electrode;
a step for forming a first line pattern mask extending in a first direction passing though above the lower electrode on the hard mask layer;
a step for forming a hard mask fin by etching the hard mask layer with the first line pattern mask as a mask;
a step for forming a second line pattern mask extending in a second direction intersecting the first direction and passing above the lower electrode after removing the first line pattern mask;
a step for forming a hard mask pillar by etching the hard mask fin using the second line pattern mask as a mask; and
a step for forming a heater electrode by etching the heater electrode layer using the hard mask pillar as a mask.

10. The method for manufacturing a semiconductor device according to claim 9, wherein the first and second line pattern masks are formed as a side wall of a photoresist film.

11. The method for manufacturing a semiconductor device according to claim 10 further comprising:
a step for forming a first insulating film of a thickness thinner than a height of the heater electrode covering the laminated structure of the hard mask pillar and the heater electrode following the step of forming the heater electrode;
a step for forming a second insulating film on the first insulating film, and
a step of flattening the second insulating film and the first insulating film until at least the upper surface of the hard mask pillar is exposed.

12. The method for manufacturing a semiconductor device according to claim 11 further comprising:
after the step of flattening the second insulating film and the first insulating film, a step for removing the hard mask pillar;
a step for filling a hole formed by removing the hard mask pillar with a phase change material; and
a step for forming an upper electrode opposed to the heater electrode on the phase change material.

13. The method for manufacturing a semiconductor device according to claim 11, wherein the step of flattening the second insulating film and the first insulating film is performed until the upper surface of the heater electrode is exposed.

14. The method for manufacturing a semiconductor device according to claim 13, further comprising a step for forming an upper electrode opposed to the heater electrode and a phase change material layer on the heater electrode.

15. The method for manufacturing a semiconductor device according to claim 11, wherein the first insulating film is an insulating film having oxidation resistant properties, and the second insulating film is an insulating film that includes oxygen.

16. The manufacturing method of the semiconductor device according to claim 15, wherein the first insulating film is a silicon nitride film, and the second insulating film is a silicon oxide film.

17. The manufacturing method of the semiconductor device according to claim 9, wherein the lower electrode is a contact plug formed in a lower interlayer insulating film.

18. A method for manufacturing a semiconductor device including a phase change memory element comprising:
a heater electrode having a pillar shape erected on a lower electrode;
an interlayer insulating film enclosing the heater electrode;
a phase change material in contact with an upper surface of the heater electrode;
and an upper electrode opposing the heater electrode via the phase change material; the interlayer insulating film being formed after the heater electrode having a pillar shape is formed by a double patterning method.

19. The method for manufacturing a semiconductor device according to claim 18, wherein a first insulating film having oxidation resistant properties and enclosing the heater electrode and a second insulating film including oxygen form the interlayer insulating film

20. The method for manufacturing a semiconductor device according to claim 19, wherein the first insulating film is a silicon nitride film, and the second insulating film is a silicon oxide film.
